(19) United States
(12) Patent Application Publication
(10) Pub. No.: US 2025/0203813 A1
(43) Pub. Date: Jun. 19, 2025

(54) DEPURATING SYSTEM FOR LIQUID-COOLED RACK-MOUNTED PROCESSING ASSEMBLIES

(71) Applicant: OVH, Roubaix (FR)

(72) Inventors: Ali CHEHADE, Moncheaux (FR); Gregory Francis Louis BAUCHART, Wattrelos (FR); Mohamad HNAYNO, Roubaix (FR)

(21) Appl. No.: 18/978,934

(22) Filed: Dec. 12, 2024

(30) Foreign Application Priority Data
Dec. 15, 2023 (EP) 23307233.9

(51) Int. Cl. H05K 7/20; C02F 1/00; C02F 1/44; C02F 103/02

(52) U.S. Cl. CPC H05K 7/20272; C02F 1/008; C02F 1/441; H05K 7/20781; C02F 2103/023; C02F 2209/05; C02F 2209/06; C02F 2303/08

(57) ABSTRACT

A depurating system and process for server racks containing liquid-cooled rack-mounted processing assemblies are presented that incorporate a tank containing a volume of liquid treated, a control module configured control an operational parameter of the treated liquid, a fluid control structure operably-coupled to the control module and configured to adjust an operational parameter of the treated liquid, and a fluid coupling section fluidly-coupled to the fluid control structure and configured to supply the treated liquid to the server racks. The injection of the treated liquid functions to purge the existing cooling liquid away from the rack-mounted processing assemblies of the server rack and replace the purged existing cooling liquid with the treated liquid while maintaining continued operations of the rack-mounted processing assemblies.

### CROSS REFERENCE

The present application claims priority to European Patent Appl. No. 23307233.9, filed Dec. 15, 2023 entitled “A DEPURATING SYSTEM FOR LIQUID-COOLED RACK-MOUNTED PROCESSING ASSEMBLIES”, the entirety of which is incorporated herein by reference.

### FIELD

The present technology generally relates to the field of datacenter liquid cooling arrangements and, in particular, to the replacement of legacy cooling liquids with a depurating liquid to service the liquid cooling needs of rack-mounted processing assemblies.

### BACKGROUND

Datacenters as well as many computer processing facilities house multitudes rack-mounted electronic processing components. In operation, such electronic processing components generate a substantial amount of heat that must be dissipated in order avoid electronic component failures and ensure continued efficient processing operations.

To this end, various liquid cooling measures have been implemented to facilitate the dissipation of heat generated by the electronic processing components. One such measure, is the use of an immersion liquid cooling technique, in which electronic components are fully submerged in a rack casing containing a non-conductive cooling liquid, such as, for example, a dielectric cooling liquid. The immersion of the electronic components within the dielectric cooling liquid achieves adequate thermal contact between the electronic components to dissipate a fair amount of generated heat.

However, there are certain electronic components, such as, for example, high-performance processing units that tend to generate more heat than other electronic components (e.g., memory boards) and dielectric liquid immersion measures may not serve to sufficiently cool such high heat-generating components. To address the cooling of these high heat-generating components, direct liquid cooling block measures have been implemented, in which liquid cooling blocks having internal channels to circulate cool water therethrough are disposed in direct thermal contact with the high heat-generating components.

The Inventors of the instant application have identified evidence of undesirable contaminants that develop, over time, due to the circulation of channelized water throughout the liquid cooling blocks and corresponding distribution channels and coupling elements. Such evidence of undesirable contaminants includes the buildup of mineral deposits, corrosion, algae, bacteria, etc. that affect the quality of the water as well as the efficient flow of the channelized water.

Hence, there is an interest in eliminating the buildup of such undesirable contaminants as well as reducing reoccurrences of the same in direct liquid cooling block implementations.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Implementations of the present technology have been developed based on certain drawbacks associated with conventional liquid cooling techniques and implementations.

In one aspect, the present technology provides a depurating system for a server rack housing rack-mounted processing assemblies that are cooled by respective liquid cooling blocks channeling a cooling liquid via a liquid cooling loop that incorporates a depurating apparatus comprising: a tank containing a volume of liquid treated with cleansing additives, a control module configured to monitor, determine, and control at least one operational parameter regarding the treated liquid, a fluid control structure operably-coupled to the control module and configured to adjust the at least one operational parameter of the treated liquid based on determinations provided by the control module, a fluid coupling section fluidly-coupled to the fluid control structure and configured to supply the treated liquid to the server rack, a server rack fluid inlet fluidly-connected to the fluid coupling section for receiving the supplied treated liquid and fluidly-coupled to an input side of the liquid cooling loop for injecting the treated liquid for distribution throughout the processing assemblies of the server rack, and a server rack fluid outlet fluidly-coupled to an output side of the liquid cooling loop for receiving the existing cooling liquid displaced by the injected treated liquid; wherein the injection of the treated liquid functions to purge the existing cooling liquid away from the rack-mounted processing assemblies of the server rack and replace the purged existing cooling liquid with the treated liquid while maintaining continued operations of the rack-mounted processing assemblies.

The depurating system further incorporates a purging pipe fluidly-coupled to the server rack unit fluid outlet and configured to receive the purged existing cooling liquid; and a liquid quality sensor (LQS) fluidly-coupled to the purging pipe for measuring quality levels of the purged existing liquid.

The depurating system provides that the treated liquid comprises reversed osmosed water containing at least one corrosion inhibiting agent and is configured to manifest certain quality levels, such as, having a pH balance of approximately between 8 and 10, an electrical conductivity of approximately less than 170 (μS/cm), an aluminum, copper, and zinc content of approximately less than 0.6 ppm and an aerobic microorganism content of approximately less than 1000 cfu/ml.

The depurating system further provides that the fluid control structure comprises at least one pump, at least one pressure sensor, at least one filter, an expansion tank, and at least one check control valve and that the fluid coupling section comprises at least one pressure control valve, at least one air vent isolation valve, and at least one shutoff flow valve.

The depurating system also provides that the injection of the treated liquid as well as the purging of the existing liquid is performed until a predetermined duration time t has lapsed.

The depurating system additionally provides that the injection of the treated liquid as well as the purging of the existing liquid is performed until quality levels of the purged existing cooling liquid, as measured by the LQS, matches the treated liquid quality levels.

In another aspect, the present technology provides a depurating process for a server rack housing rack-mounted processing assemblies that are cooled by respective liquid cooling blocks channeling a cooling liquid via a liquid cooling loop that comprises: detecting an internal volume and pressure of a liquid tank (110A) containing a treated depurating liquid, the treated depurating liquid comprising reversed osmosed water containing at least one corrosion inhibiting agent; determining whether the internal volume and/or pressure of the treated liquid tank is below an acceptable threshold value; upon determining that the internal volume and/or pressure of the treated liquid tank is below the acceptable threshold value, shut down the process and send an alert message. And, upon determining that the internal volume and/or pressure of the treated liquid tank meets the acceptable threshold value, execute the depurating process by actuating pumps corresponding to liquid distribution chains of the treated liquid; selecting at least one of the liquid distribution chains for distributing the treated liquid to the rack-mounted processing assembly; activate an expansion tank to ensure constant pressure and volume of the treated liquid to be distributed to the rack-mounted processing assembly; and commence injection flow of the treated liquid into the liquid cooling loop of the server rack unit. The process operates such that the injection flow of the treated liquid functions to purge existing cooling liquid from the rack-mounted processing assemblies of the server rack and replace the purged existing cooling liquid with the treated liquid while maintaining continued operations of the rack-mounted processing assemblies.

Moreover, in one implementation the depurating process is performed until a predetermined duration time t has lapsed. And, in another implementation, the depurating process is performed until quality levels of the purged existing cooling liquid match the treated liquid quality levels.

In the context of the present specification, unless expressly provided otherwise, a computer system may refer, but is not limited to, an “electronic device”, an “operation system”, a “system”, a “computer-based system”, a “controller unit”, a “monitoring device”, a “control device” and/or any combination thereof appropriate to the relevant task described.

Furthermore, in the context of the present specification, unless expressly provided otherwise, the expression “computer-readable medium” and “memory” are intended to include media of any nature and kind whatsoever, non-limiting examples of which include RAM, ROM, disks (CD-ROMs, DVDs, floppy disks, hard disk drives, etc.), USB keys, flash memory cards, solid state-drives, and tape drives. Still in the context of the present specification, “a” computer-readable medium and “the” computer-readable medium should not be construed as being the same computer-readable medium. To the contrary, and whenever appropriate, “a” computer-readable medium and “the” computer-readable medium may also be construed as a first computer-readable medium and a second computer-readable medium.

Additionally, in the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned object and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects, and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 illustrates a high-level functional block diagram of a depurating system, in accordance with the nonlimiting implementations of the present technology;

FIG. 2A illustrates a high-level functional block diagram of a fluid control structure for the depurating system, in accordance with the nonlimiting implementations of the present technology;

FIG. 2B illustrates a high-level functional block diagram of a fluid coupling section for the depurating system, in accordance with the nonlimiting implementations of the present technology;

FIG. 3 illustrates a high-level schematic of the fluid coupling section connected to rack units for the depurating system, in accordance with the nonlimiting implementations of the present technology;

FIG. 4 illustrates a high-level flow diagram for the depurating process, in accordance with the nonlimiting implementations of the present technology; and

FIG. 5 is block diagram of a controller in accordance with an implementation of the present technology.

It should be appreciated that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future. Thus, for example, it will be appreciated by those skilled in the art that any block diagrams herein represent conceptual views of illustrative circuitry embodying the principles of the present technology. Similarly, it will be appreciated that any flowcharts, flow diagrams, state transition diagrams, pseudo-code, and the like represent various processes that may be substantially represented in non-transitory computer-readable media and so executed by a computer or processor, whether or not such computer or processor is explicitly shown.

The functions of the various elements shown in the FIGS. including any functional block labeled as a “processor”, may be provided through the use of dedicated hardware as well as hardware capable of executing software in association with appropriate software. When provided by a processor, the functions may be provided by a single dedicated processor, by a single shared processor, or by a plurality of individual processors, some of which may be shared. In some implementations of the present technology, the processor may be a general-purpose processor, such as a central processing unit (CPU) or a processor dedicated to a specific purpose, such as a digital signal processor (DSP). Moreover, explicit use of the term a “processor” should not be construed to refer exclusively to hardware capable of executing software, and may implicitly include, without limitation, application specific integrated circuit (ASIC), field programmable gate array (FPGA), read-only memory (ROM) for storing software, random access memory (RAM), and non-volatile storage. Other hardware, conventional and/or custom, may also be included.

Software modules, or simply modules which are implied to be software, may be represented herein as any combination of flowchart elements or other elements indicating performance of process steps and/or textual description. Such modules may be executed by hardware that is expressly or implicitly shown. Moreover, it should be understood that module may include for example, but without being limitative, computer program logic, computer program instructions, software, stack, firmware, hardware circuitry or a combination thereof which provides the required capabilities.

Given this fundamental understanding, the disclosed implementations are directed to a depurating system for liquid-cooled rack-mounted processing assemblies that is configured to eliminate the buildup of undesirable contaminants and replace liquid cooling liquid with a treated fluid reduce reoccurrences of the same in direct liquid cooling block implementations. The depurating system is capable of performing the depurating process while the processing assemblies are in operation with no downtime.

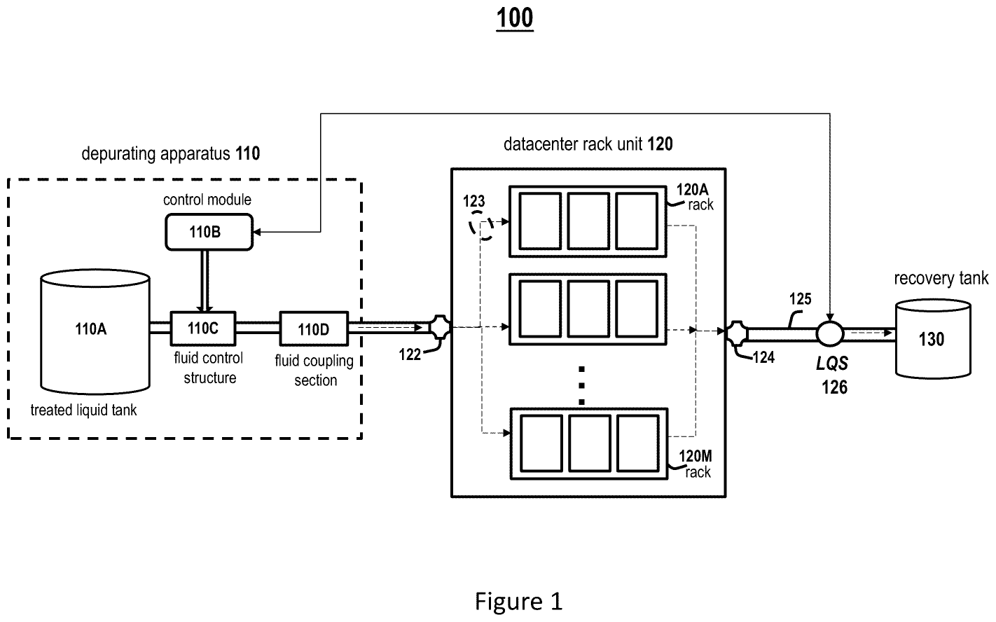

FIG. 1 illustrates a high-level functional block diagram of a depurating system 100, in accordance with the nonlimiting implementations of the present technology. As depicted, depurating system 100 generally comprises a depurating apparatus 110 that is in fluid communication and contact with a datacenter rack unit 120.

Starting with the datacenter rack unit 120, the rack unit 120 houses a plurality of racks, in which each rack comprises one or more rack-mounted processing assemblies 120A-120M. Each of the rack-mounted processing assemblies 120A-120M contain heat-generating processing components (not shown) which are cooled by liquid cooling blocks (not shown) that are arranged to be in direct thermal contact with the heat-generating components. In turn, each of the liquid cooling blocks employ internal channels that are fluidly-coupled to a server rack liquid cooling loop 123 which conveys cool liquid (e.g water) and circulates the channelized cool liquid throughout the liquid cooling blocks. The server rack liquid cooling loop 123 may be constructed from flexible materials (e.g., rubber, plastic, etc.), rigid materials (e.g., metal, PVC piping, etc.), or any combination of thereof capable of securely conveying cool liquid.

The datacenter rack unit 120 also implements a rack unit liquid inlet 122, a rack unit liquid outlet 124, a purging pipe 125. In some implementations, the datacenter rack unit 120 may also include a liquid quality sensor (LQS) 126 fluidly connected to the purging pipe 125 as well as operably-connected to a control module 110B (see below). The liquid inlet 122 is fluidly coupled to an input side of the server rack liquid cooling loop 123 to supply cool liquid to the liquid cooling blocks while the liquid outlet 124 is fluidly-coupled to an output side of the liquid cooling loop 123 to receive the existing liquid containing contaminant residues (i.e., “dirty liquid”). The dirty liquid is forwarded to the purge pipe 125 for disposal or recleaning/recirculation, in which the LQS 126 may measure quality levels of the purged dirty liquid. The measured quality levels may include pH balance, electrical conductivity, aluminum, copper, and zinc content, and/or aerobic microorganism.

For depurating purposes, the present technology exploits the infrastructure provided by the rack liquid inlet 122, rack liquid cooling loop 123, and rack liquid outlet 124 to circulate a treated liquid throughout the liquid cooling loop 123 and related components and purge the existing dirty liquid from the racks. In certain implementations, a recovery tank 130 may be provided that receives the purged dirty liquid via the purging pipe 125.

Turning to the depurating apparatus 110, the apparatus 110 comprises a treated liquid tank 110A, a control module 110B, a fluid control structure 110C operably- and communicatively-coupled to the control module 110B, and a fluid coupling section 110D.

The treated liquid tank 110A is configured to contain a volume of treated liquid containing additives designed to substantially eliminate contaminants and corrosive deposits that have built up within liquid cooling blocks, the server rack liquid cooling loop 123, and corresponding coupling elements. As will be described below, the treated liquid is to be injected into the server rack liquid cooling loop 123 and circulated therethrough to substantially eliminate contaminants and deposits, purge the existing (i.e., “dirty”) liquid containing such impurities, and replace the dirty liquid with the treated liquid. This depurating cycle is to be executed while maintaining the operations of the data processing assemblies 120A-120M active with no downtime in processing performance.

The treated liquid may include water with certain additives/agents having contaminant cleansing and anticorrosive properties. In certain implementations, the treated liquid comprises reversed osmosed water containing at least one corrosion-inhibiting agent. The treated liquid may be further processed and filtered to manifest certain liquid quality levels, such as, for example, a pH balance of approximately between 8 and 10, an electrical conductivity of approximately less than 170 (μS/cm), an aluminum, copper, and zinc content of approximately less than 0.6 ppm, and an aerobic microorganism content of approximately less than 1000 cfu/ml.

The control module 110B monitors and determines operational parameters of the treated liquid to be supplied to the rack-mounted processing assemblies 120A-120M and is operably-coupled to the LQS 126. Such operational parameters may include pump pressure levels and volume flow levels of the treated liquid to be supplied to the processing assemblies 120A-120M as well as liquid quality levels being purged therefrom.

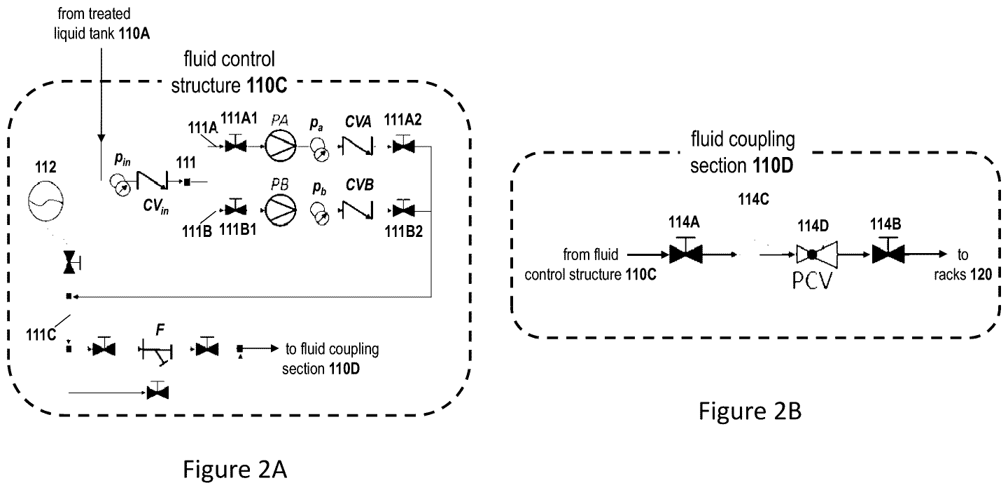

The fluid control structure 110C is operably- and communicatively-coupled to the control module 110B and is configured to adjust the at least one operational parameter of the treated liquid based on determinations provided by the control module 110B. As best seen in FIG. 2A, which illustrates a high-level functional block diagram of the fluid control structure 110C in accordance with the implementations of the present technology, fluid control structure 110C includes at least one pump PA, PB, at least one pressure sensor pᵢₙ, pₐ, p_{b}, at least one check valve CVᵢₙ, CVA, CVB, at least one shutoff control valve 111A1, 111A2, 111B1, 111B2, an expansion tank 112, and a filter F incorporated along respective liquid distribution chains 111A, 111B, 111C.

In particular, the control structure 110C receives the treated liquid and first determines whether the tank pressure/volume are proper based on the measured value by pressure sensor Pᵢₙ. The control structure 110C then implements an initial check valve CVᵢₙ to prevent backflow of the treated liquid seeping back into liquid tank 110A. The treated liquid is then supplied to a junction coupler 111 configured to provide the treated liquid to one or more parallel liquid distribution chains 111A, 111B.

Each of the parallel liquid distribution chains 111A, 111B respectively includes a front-end control valve 111A1 (or 111B1) for allowing/preventing ingress of the treated liquid, a pump PA (or PB) to provide the necessary pressure flow of the treated liquid, a pressure sensor pₐ (or p_{b}) to detect and confirm the pressure flow, and a check valve CVA (or CVB) to prevent backflow of the treated liquid, and a back-end control valve 111A2 (or 111B2) for allowing/preventing egress of the treated liquid. By virtue of providing a parallel configuration, either one or both of the distribution chains 111A, 111B may be selected to supply the required volume and pressure of the treated liquid by virtue of turning on/off the front-end valves 111A1, 111B1 and back-end valves 111A2, 111B2.

The treated liquid outputted by one or both of the liquid distribution chains 111A, 111B is received by liquid distribution chain 111C. As shown, liquid distribution chain 111C is fluidly coupled to an expansion tank 112 that is configured to ensure that the treated liquid pressure and volume are constant throughout the depurating cycle. The liquid distribution chain 111C further comprises a filter F to filter out any impurities/contaminants that may have been picked up by the treated liquid as it circulates throughout the components of the liquid distribution chains 111A, 111B and expansion tank 112. The liquid distribution chain 111C also comprises a variety of control shutoff valves for isolating the flow of the treated liquid.

As noted above, the operational parameters such as, pump/pressure values and volume flow values, the selection of the distribution chains 111A, 111B and filtering are implemented in accordance with the determinations provided by the control module 110B in order to conduct the depurating process while maintaining the data processing assemblies 120A-120M operational.

Returning back to FIG. 1, as shown, the depurating apparatus 110 further includes a fluid coupling section 110D that is fluidly connected to the control structure 110C. As best seen in FIG. 2B, which illustrates a high-level functional block diagram of the fluid coupling section 110D in accordance with the implementations of the present technology, the coupling section 110D comprises a front-end valve 114A for allowing/preventing ingress of the filtered treated liquid supplied by the fluid control structure 110C, a pressure control valve PCV, an air vent isolation valve AAV 114C, and a back-end valve 114B for allowing/preventing the supply of the treated liquid into the server rack liquid cooling loop 123.

In particular, the fluid coupling section 110D receives the treated liquid from the fluid control structure 110C and incorporates a front-end valve 114A for allowing/preventing ingress of the treated liquid. Upon ingress of the treated liquid, the automatic air vent valve AAV 114C operates to bleed any air (i.e., air bubbles/pockets) out of the treated liquid within the closed loop system and ensure that the treated liquid is substantially free of air pockets.

The treated liquid is then directed to a pressure control valve (PCV) 114D configured to enable the injection of the treated liquid into the server rack liquid cooling loop 123 while maintaining the internal pressure and volume levels of the existing liquid within the server rack liquid cooling loop 123 and liquid cooling blocks at constant adequate levels. After the PCV 114D, the treated liquid is forwarded to a back-end valve 114B for allowing/preventing the treated liquid to be injected into the fluidly-coupled server rack liquid cooling loop 123 for circulation therethrough and purging of the existing liquid. In so doing, the depurating operation cycle is executed while maintaining the data processing assemblies 120A-120M operational throughout the process.

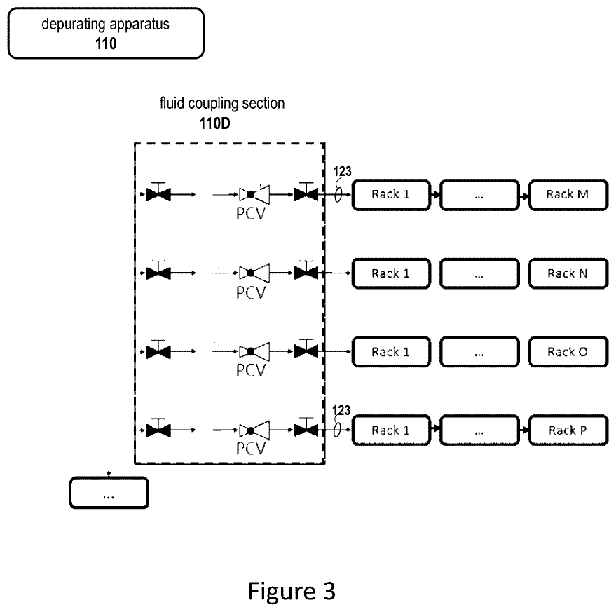

With this said, FIG. 3 illustrates a high-level schematic of the fluid coupling section 110D connected to the datacenter server rack units 120, in accordance with the non-limiting implementations of the present technology. As shown, the fluid coupling 110D of the depurating apparatus 110 is configured to fluidly connect to a plurality of racks for supplying the treated liquid for circulation via the server rack units liquid cooling loop 123 and purging the existing “dirty” liquid away, while maintaining the processing assemblies of the server rack units 120 in operation with no downtime.

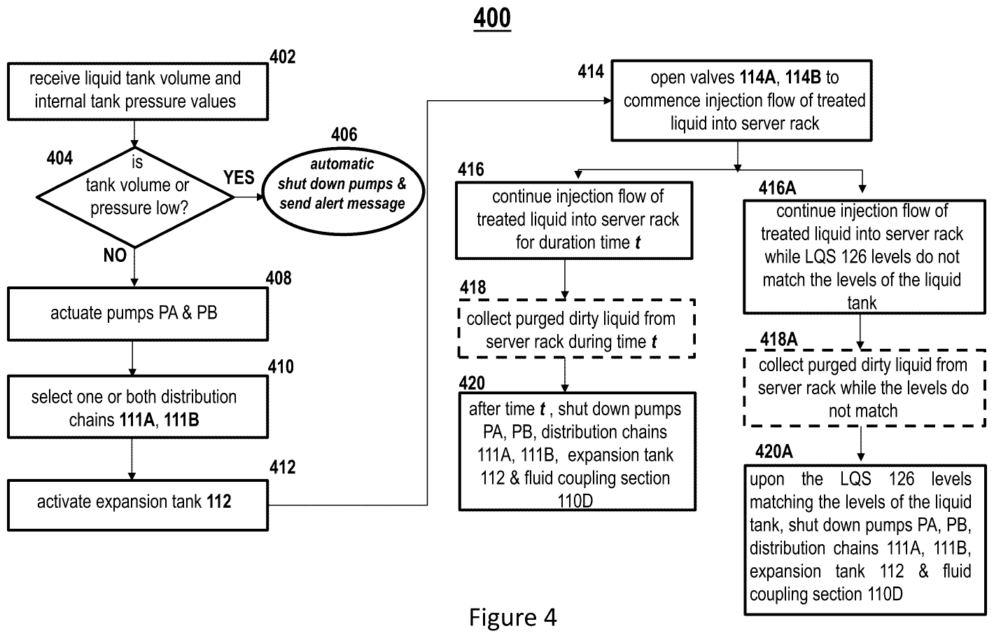

FIG. 4 illustrates a high-level flow diagram for the depurating process 400, in accordance with the nonlimiting implementations of the present technology. As noted above, depurating process 400 is configured to be executed while maintaining the data processing assemblies 120A-120M operational throughout the process.

In the disclosed implementation, depurating process 400 or portions thereof are referenced as being executed by control module 110B for tractability purposes. However, the exact entity or entities executing depurating process 400 or portions thereof should not be interpreted as being limiting with regard to the concepts provided by the instant disclosure.

With this said, process 400 commences at task block 402 where the volume and internal pressure of the treated liquid tank is received based on the measured values by pressure sensor Pᵢₙ. In certain implementations, the measured pressure value should register approx. between 0.05-0.2 bar for proper operations. At decision block 404, process 400 determines whether the volume and/or internal pressure of the treated liquid tank is below the threshold values for proper operations. If so, at task block 406, process 400 automatically shuts down pumps PA, PB and transmits an alert message to operators. If the volume and/or internal pressure of the treated liquid tank are not below the threshold values for proper operations, process 400 moves to task block 408 in which pumps PA, PB corresponding the distribution chains 111A, 111B are actuated for operation.

At task block 410, process 400 selects one or both distribution chains 111A, 111B of the fluid control structure 110C to supply the treated liquid to be injected into the server rack(s). The selection of the distribution chains 111A, 111B may be based on the estimated cooling liquid demands of particular server rack(s) and/or the pressure/volume levels required for proper operations.

At task block 412, the expansion tank 112 of the fluid control structure 110C is activated to ensure the constant proper pressure and volume flow of the treated liquid to be supplied to the server rack(s). Then, at task block 414, valves 114A, 114B of the fluid coupling section 110D are opened to commence the flow of the treated liquid to be injected into the server rack(s). As noted above, the AAV 114C operates to bleed out any air pockets or bubbles from the treated liquid and the PCV 114D operates to maintain the internal pressure and volume levels of the existing liquid within the server rack liquid cooling loop 123 and liquid cooling blocks at constant adequate levels (e.g., approx. between 0.2 to 0.9 bar).

After the injection flow of the treated liquid has commenced, the present technology embodies two implementations for the duration of the injection procedure. Therefore, in a first implementation of the present technology, at task block 416, the injection flow of the treated liquid into the server rack(s) continues for a predetermined duration time t. The duration time t may be based on, for example, historical practices and experience. Then, at task block 418, the “dirty” liquid purged from the rack(s) may be collected for recleaning/re-filtering/recirculation purposes.

Finally, after duration time t has lapsed, process 400 shuts down pumps PA, PB, distribution chains 111A, 111B, expansion tank 112, and fluid coupling section 110D.

Alternatively, in another implementation of the present technology, at task block 416A, the injection flow of the treated liquid into the server rack(s) continues while the quality levels measured by the LQS 126 of the purged dirty liquid do not match the registered quality levels of the treated liquid in the liquid tank 110A.

At task block 418A, the dirty liquid purged from the server rack(s) may be collected for recleaning/re-filtering/recirculation purposes. Then, upon the LQS 126 quality levels matching the quality levels of the treated liquid in the liquid tank 110A, at task block 420A, process 400 shuts down pumps PA, PB, distribution chains 111A, 111B, expansion tank 112, and fluid coupling section 110D.

In this manner, the depurating system 100 and corresponding process 400 effectively eliminate the buildup of undesirable contaminants throughout liquid cooling configurations of rack-mounted data processing assemblies as well as reduce reoccurrences of the same by furnishing treated cooling liquids. Moreover, the depurating system 100 and corresponding process 400 are capable of performing depurating cycle while the data processing assemblies are still in operation with no processing downtime.

While the above-described implementations have been described and shown with reference to particular steps performed in a particular order, it will be understood that these steps may be combined, sub-divided, or re-ordered without departing from the teachings of the present technology. At least some of the steps may be executed in parallel or in series. Accordingly, the order and grouping of the steps is not a limitation of the present technology.

It will be appreciated that at least some of the operations of the method 1300 may also be performed by computer programs, which may exist in a variety of forms, both active and inactive. Such as, the computer programs may exist as software program(s) comprised of program instructions in source code, object code, executable code or other formats. Any of the above may be embodied on a computer readable medium, which includes storage devices and signals, in compressed or uncompressed form. Representative computer readable storage devices include conventional computer system RAM (random access memory), ROM (read only memory), EPROM (erasable, programmable ROM), EEPROM (electrically erasable, programmable ROM), and magnetic or optical disks or tapes. Representative computer readable signals, whether modulated using a carrier or not, are signals that a computer system hosting or running the computer program may be configured to access, including signals downloaded through the Internet or other networks. Concrete examples of the foregoing include distribution of the programs on a CD ROM or via Internet download. In a sense, the Internet itself, as an abstract entity, is a computer readable medium. The same is true of computer networks in general.

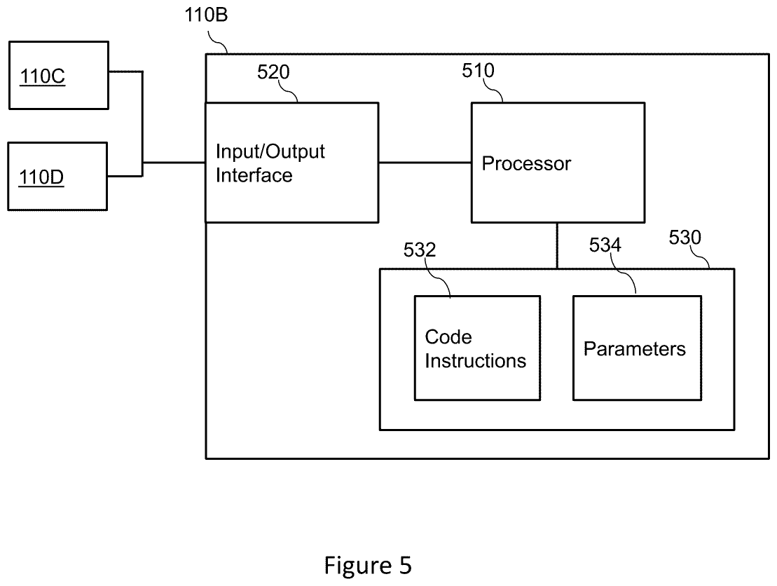

As an example, FIG. 5 is a schematic block diagram of the control module 110B of the depurating system 100 according to some implementations of the present technology. The control module 110B comprises a processor or a plurality of cooperating processors (represented as a processor 510 for simplicity), a memory device or a plurality of memory devices (represented as a memory device 530 for simplicity), and an input/output interface 520 allowing the control module 110B to communicate with other components of the depurating system 100 and/or other components in remote communication with the depurating system 100. The processor 510 is operatively connected to the memory device 530 and to the input/output interface 520. The memory device 530 includes a storage for storing parameters 534. The memory device 530 may comprise a non-transitory computer-readable medium for storing code instructions 532 that are executable by the processor 510 to allow the control module 110B to perform the various tasks allocated to the control module 110B in the process 400.

The control module 110B is operatively connected, via the input/output interface 520, to the fluid control structure 110C. In some implementations, the control module 110B is also operatively connected to the fluid coupling section 110D. The control module 110B executes the code instructions 532 stored in the memory device 530 to implement the various above-described functions that may be present in a particular implementation. FIG. 5 as illustrated represents a non-limiting implementation in which the control module 110B orchestrates operations of the process 400. This particular implementation is not meant to limit the present disclosure and is provided for illustration purposes.

It will be understood that the features and examples above are not meant to limit the scope of the present disclosure to a single implementation, as other implementations are possible by way of interchange of some or all of the described or illustrated elements. Moreover, where certain elements of the present disclosure can be partially or fully implemented using known components, only those portions of such known components that are necessary for an understanding of the present disclosure are described, and detailed descriptions of other portions of such known components are omitted so as not to obscure the disclosure. In the present specification, an implementation showing a singular component should not necessarily be limited to other implementations including a plurality of the same component, and vice-versa, unless explicitly stated otherwise herein. Moreover, applicants do not intend for any term in the specification or claims to be ascribed to an uncommon or special meaning unless explicitly set forth as such. Further, the present disclosure encompasses present and future known equivalents to the known components referred to herein by way of illustration.

The present description of the specific implementations so fully reveals the general nature of the disclosure that others can, by applying knowledge within the skill of the relevant art(s) (including the contents of any documents cited and incorporated by reference herein), readily modify and/or adapt for various applications such specific implementations, without undue experimentation and without departing from the general concept of the present disclosure. Such adaptations and modifications are therefore intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one skilled in the relevant art(s).

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. A depurating system for a server rack housing rack-mounted processing assemblies that are cooled by respective liquid cooling blocks channeling a cooling liquid via a liquid cooling loop, comprising:
a depurating apparatus comprising:
a tank containing a volume of liquid treated with cleansing additives,
a control module configured to monitor, determine, and control at least one operational parameter regarding the treated liquid,
a fluid control structure operably-coupled to the control module and configured to adjust the at least one operational parameter of the treated liquid based on determinations provided by the control module, and
a fluid coupling section fluidly-coupled to the fluid control structure and configured to supply the treated liquid to the server rack, the fluid coupling section comprising a pressure control valve (PCV) and a back-end valve;
a server rack fluid inlet fluidly-connected to the fluid coupling section for receiving the supplied treated liquid and fluidly-coupled to an input side of the liquid cooling loop for injecting the treated liquid for distribution throughout the processing assemblies of the server rack;
a server rack fluid outlet fluidly-coupled to an output side of the liquid cooling loop for receiving the existing cooling liquid displaced by the injected treated liquid;
wherein the PCV is configured to provide the injection of the treated liquid functions into the liquid cooling loop to purge the existing cooling liquid away from the rack-mounted processing assemblies of the server rack and replace the purged existing cooling liquid with the treated liquid while maintaining continued operations of the rack-mounted processing assemblies and
wherein the back-end valve is configured to control the supply of the treated liquid into the server rack liquid cooling loop.

2. The depurating system of claim 1, further comprising:
a purging pipe fluidly-coupled to the server rack unit fluid outlet and configured to receive the purged existing cooling liquid; and
a liquid quality sensor (LQS) fluidly-coupled to the purging pipe for measuring quality levels of the purged existing liquid.

3. The depurating system of claim 1, wherein the treated liquid comprises reversed osmosed water containing at least one corrosion inhibiting agent.

4. The depurating system of claim 1, wherein the treated liquid further comprises quality levels having a pH balance of approximately between 8 and 10, an electrical conductivity of approximately less than 170 (μS/cm), an aluminum, copper, and zinc content of approximately less than 0.6 ppm and an aerobic microorganism content of approximately less than 1000 cfu/ml.

5. The depurating system of claim 1, wherein the fluid control structure comprises at least one pump (PA, PB), at least one pressure sensor (pᵢₙ, pₐ, p_{b}), at least one filter (F), an expansion tank, and at least one check control valve (CVᵢₙ, CVA, CVB).

6. The depurating system of claim 1, wherein the fluid coupling section further comprises at least one air vent isolation valve, and at least one shutoff flow valve.

7. The depurating system of claim 1, wherein the at least one operational parameter includes one of a tank internal volume level, a tank internal pressure level, and/or a pump (PA, PB) pressure level.

8. The depurating system of claim 1, wherein the injection of the treated liquid is performed until a predetermined duration time t has lapsed.

9. The depurating system of claim 2, wherein the injection of the treated liquid is performed until quality levels of the purged existing cooling liquid, as measured by the LQS, matches the treated liquid quality levels.

10. A depurating process for a server rack housing rack-mounted processing assemblies that are cooled by respective liquid cooling blocks channeling a cooling liquid via a liquid cooling loop, comprising:
detecting an internal volume and pressure of a liquid tank containing a treated depurating liquid, the treated depurating liquid comprising reversed osmosed water containing at least one corrosion inhibiting agent;
determining whether the internal volume and/or pressure of the treated liquid tank is below an acceptable threshold value;
upon determining that the internal volume and/or pressure of the treated liquid tank is below the acceptable threshold value, shut down the process and send an alert message;
upon determining that the internal volume and/or pressure of the treated liquid tank meets the acceptable threshold value, execute the process by:
actuating pumps corresponding to liquid distribution chains of the treated liquid;
selecting at least one of the liquid distribution chains for distributing the treated liquid to the rack-mounted processing assembly;
activate an expansion tank to ensure constant pressure and volume of the treated liquid to be distributed to the rack-mounted processing assembly; and
commence injection flow of the treated liquid into the liquid cooling loop of the server rack unit;
wherein the injection flow of the treated liquid functions to purge existing cooling liquid from the rack-mounted processing assemblies of the server rack and replace the purged existing cooling liquid with the treated liquid while maintaining continued operations of the rack-mounted processing assemblies.

11. The depurating process of claim 10, wherein the treated liquid further comprises quality levels having a pH balance of approximately between 8 and 10, an electrical conductivity of approximately less than 170 (μS/cm), an aluminum, copper, and zinc content of approximately less than 0.6 ppm and an aerobic microorganism content of approximately less than 1000 cfu/ml.

12. The depurating process of claim 10, wherein the injection of the treated liquid and the purging of existing liquid is performed until a predetermined duration time t has lapsed.

13. The depurating process of claim 11, wherein the injection of the treated liquid and the purging of existing liquid is performed until quality levels of the purged existing cooling liquid match the treated liquid quality levels.

14. The depurating process of claim 12, wherein after the lapse of during time t, the pumps, distribution chains, expansion tank and fluid coupling section are shut down.

15. The depurating process of claim 13, wherein upon the quality levels of the purged existing cooling liquid matching the treated liquid quality levels, pumps, distribution chains, expansion tank and fluid coupling section are shut down.
